(19) United States
(12) Patent Application Publication
(10) Pub. No.: US 2025/0259925 A1
(43) Pub. Date: Aug. 14, 2025

(54) SEMICONDUCTOR DEVICE AND METHOD OF MANUFACTURING THE SAME

(71) Applicant: Renesas Electronics Corporation, Tokyo (JP)

(72) Inventors: Tohru KAWAI, Tokyo (JP); Nobuhito SHIRAISHI, Tokyo (JP)

(21) Appl. No.: 18/955,089

(22) Filed: Nov. 21, 2024

(30) Foreign Application Priority Data
Feb. 14, 2024 (JP) 2024-019975

(51) Int. Cl. H01L 23/522; H01L 21/768; H01L 23/373

(52) U.S. Cl. CPC H01L 23/5228; H01L 21/76894; H01L 23/3738; H10D 1/474

(57) ABSTRACT

A semiconductor device includes a first resistor element. The first resistor element includes a first resistor, and a second resistor electrically connected in series to the first resistor. The first resistor and the second resistor are each made of a first material. One of a temperature coefficient of an electrical resistance value of the first resistor and a temperature coefficient of an electrical resistance value of the second resistor is a positive value. The other of the temperature coefficient of the electrical resistance value of the first resistor and the temperature coefficient of the electrical resistance value of the second resistor is a negative value.

### CROSS-REFERENCE TO RELATED APPLICATIONS

The disclosure of Japanese Patent Application No. 2024-019975 filed on Feb. 14, 2024, including the specification, drawings and abstract is incorporated herein by reference in its entirety.

### BACKGROUND

The present disclosure relates to a semiconductor device and a method of manufacturing the same.

There are disclosed techniques listed below.
[Patent Document 1] Japanese Unexamined Patent Application Publication No. 2020-35899

Patent Document 1 discloses a semiconductor device. The semiconductor element described in Patent Document 1 includes a resistor element. The resistor element is configured by connecting a plurality of conductive layers to each other. A first conductive layer among the plurality of conductive layers has a positive temperature coefficient, and a second conductive layer among the plurality of conductive layers has a negative temperature coefficient. Thus, in the semiconductor device described in Patent Document 1, the temperature coefficient of the resistor element is reduced.

### SUMMARY

In the semiconductor device described in Patent Document 1, the second conductive layer is formed of a material different from the first conductive layer. Other problems and novel features will become apparent from the description of this specification and the accompanying drawings.

A semiconductor device of the present disclosure includes a first resistor element. The first resistor element has a first resistor and a second resistor, which is electrically connected in series to the first resistor. The first resistor and the second resistor are each made of a first material. One of a temperature coefficient of an electrical resistance value of the first resistor and a temperature coefficient of an electrical resistance value of the second resistor is a positive value. The other of the temperature coefficient of the electrical resistance value of the first resistor and the temperature coefficient of the electrical resistance value of the second resistor is a negative value.

According to the semiconductor device of the present disclosure, it is possible to reduce the temperature coefficient of the resistor element including the first resistor and the second resistor formed of the same type of material as the first resistor.

### BRIEF DESCRIPTION OF THE DRAWINGS

FIG. 1 is a first plan view of a semiconductor device DEV1.

FIG. 2 is a second plan view of the semiconductor device DEV1.

FIG. 3 is a cross-sectional view of the semiconductor device DEV1 along III-III in FIG. 1.

FIG. 4 is a cross-sectional view of the semiconductor device DEV1 along IV-IV in FIG. 2.

FIG. 5 is a cross-sectional view of the semiconductor device DEV1 along V-V in FIG. 2.

FIG. 6 is a cross-sectional view of the semiconductor device DEV1 along VI-VI in FIG. 2.

FIG. 7 is a view showing a manufacturing step of the semiconductor device DEV1.

FIG. 8 is a cross-sectional view for explaining the third interlayer insulating film formation step S7.

FIG. 9 is a cross-sectional view for explaining the second via plug formation step S8.

FIG. 10 is a cross-sectional view for explaining the resistor formation step S9.

FIG. 11 is a cross-sectional view for explaining the fourth interlayer insulating film formation step S10.

FIG. 12 is a cross-sectional view for explaining the temperature coefficient adjustment step S11.

FIG. 13 is a graph showing the relationship between the temperature coefficient and sheet resistance of the resistor RES2 and the annealing temperature.

FIG. 14 is a plan view of a semiconductor device DEV2.

FIG. 15 is a plan view of the semiconductor device DEV2.

FIG. 16 is a view showing the manufacturing step of the semiconductor device DEV2.

FIG. 17 is a plan view of a semiconductor device DEV3.

FIG. 18 is a cross-sectional view of a semiconductor device DEV4.

FIG. 19 is a view showing the manufacturing step of the semiconductor device DEV4.

FIG. 20 is a cross-sectional view of a semiconductor device DEV5.

FIG. 21 is a plan view of the semiconductor device DEV5.

FIG. 22 is a view showing the manufacturing step of the semiconductor device DEV5.

### DETAILED DESCRIPTION

The details of embodiments of the present disclosure are described with reference to the drawings. In the following drawings, identical or corresponding parts are designated with the same reference numerals, and redundant descriptions are not repeated.

### First Embodiment

A semiconductor device DEV1 according to the first embodiment is described.

### Configuration of Semiconductor Device DEV1

The configuration of the semiconductor device DEV1 is described below.

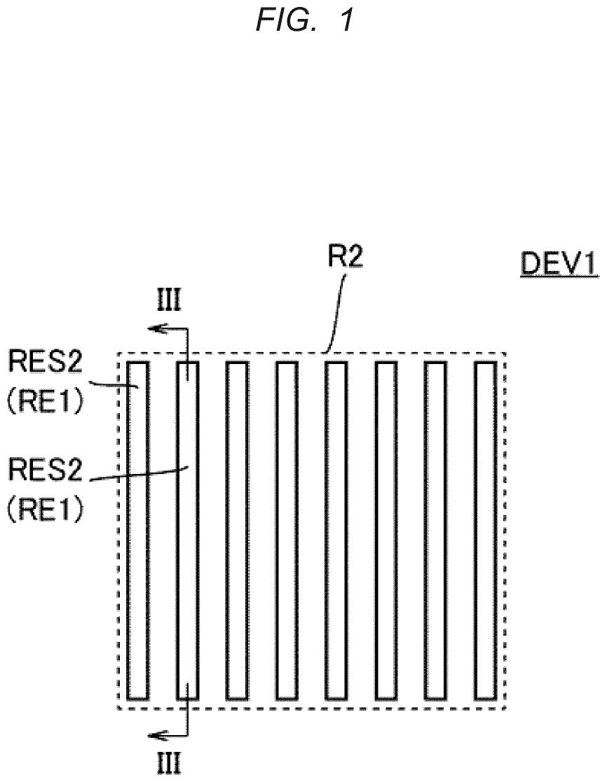

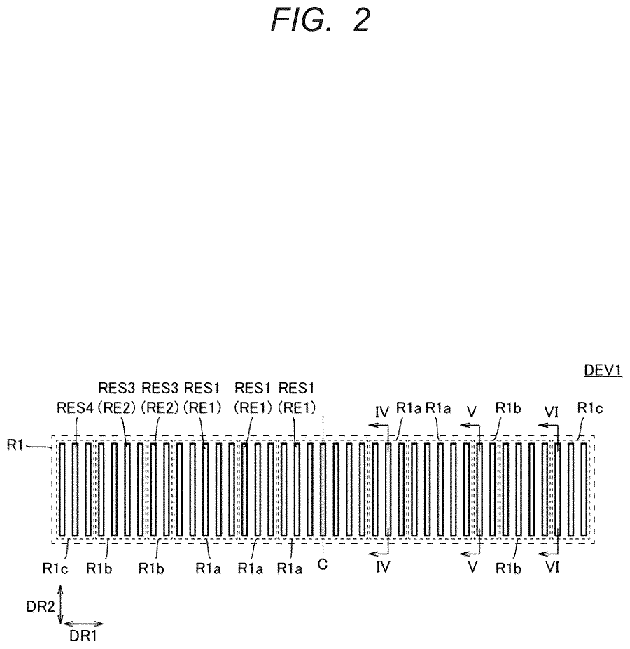

As shown in FIGS. 1 and 2, the semiconductor device DEV1 has a resistor array region R1 and an adjustment region R2 in plan view. The adjustment region R2 is different from the resistor array region R1.

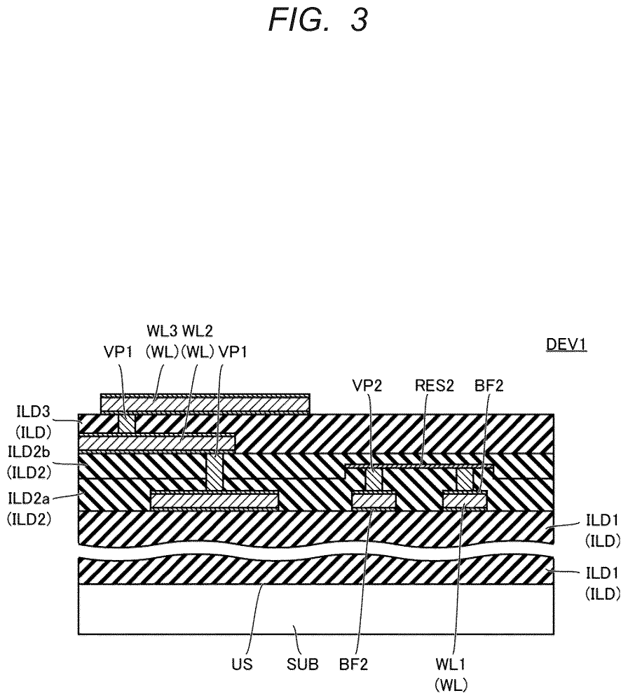

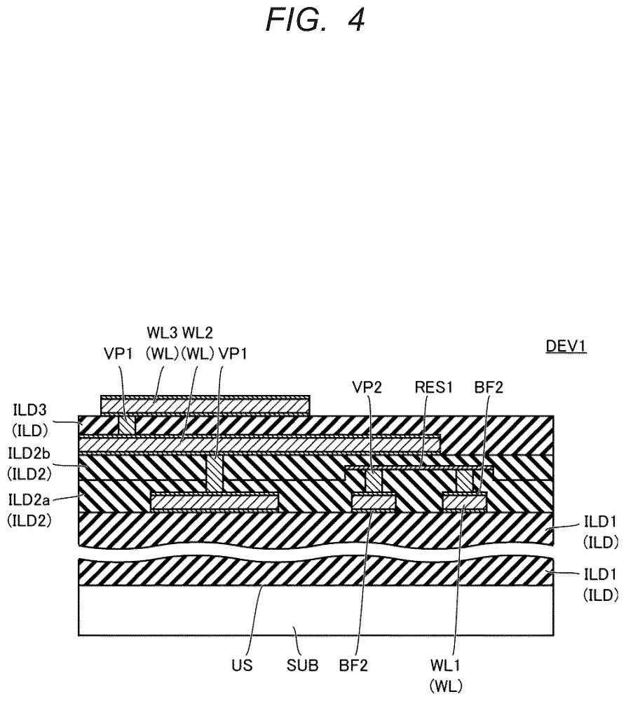

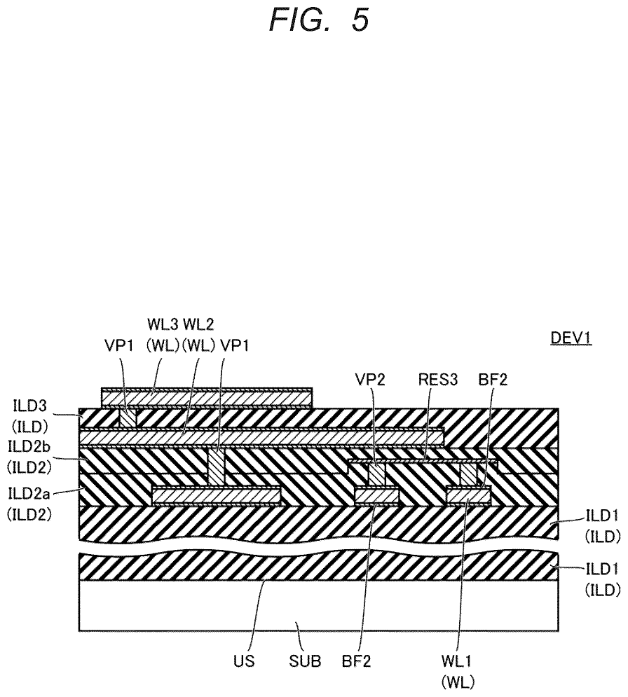

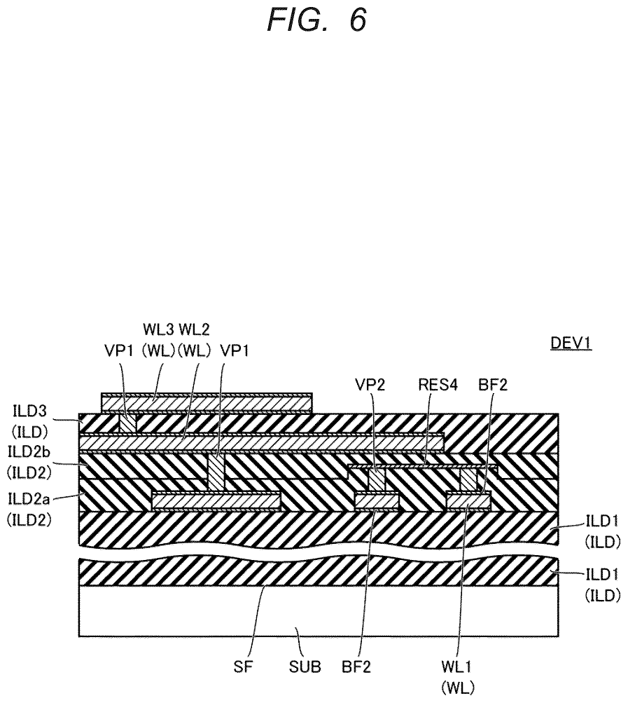

As shown in FIGS. 3 to 6, the semiconductor device DEV1 has a semiconductor substrate SUB, an interlayer insulating film ILD, a wiring WL, a resistor RES1, a resistor RES2, a resistor RES3, and a resistor RES4.

A material of the semiconductor substrate SUB is, for example, single-crystal silicon. The semiconductor substrate SUB has an upper surface US. Although not shown, a source region and a drain region which are separated from each other and a well region surrounding the source region and the drain region are formed at the upper surface US. Also, although not shown, a gate insulating film is arranged on a portion of the upper surface US arranged between the source region and the drain region, and a gate electrode is arranged on the gate insulating film. The source region, the drain region, the well region, the gate insulating film, and the gate electrode configure a transistor TR (not shown).

A material of the interlayer insulating film ILD is, for example, silicon oxide. A plurality of interlayer insulating films ILD are stacked on the upper surface US. The interlayer insulating film ILD has a plurality of interlayer insulating films ILD1, an interlayer insulating film ILD2, and an interlayer insulating film ILD3. The plurality of interlayer insulating films ILD1 are stacked on the upper surface US. The interlayer insulating film ILD2 is arranged on the uppermost interlayer insulating film ILD1 among the plurality of interlayer insulating films ILD1. The interlayer insulating film ILD3 is arranged on the interlayer insulating film ILD2. The interlayer insulating film ILD2 has a first layer ILD2a and a second layer ILD2b. The second layer ILD2b is arranged on the first layer ILD2a.

A material of the wiring WL is, for example, aluminum or an aluminum alloy. The plurality of wirings WL have a plurality of wirings WL1, a wiring WL2, and a wiring WL3. The plurality of wirings WL1 are arranged on the interlayer insulating film ILD1. The wiring WL2 is arranged on the interlayer insulating film ILD2. The wiring WL3 is arranged on the interlayer insulating film ILD3. The wiring WL1 is covered with the interlayer insulating film ILD1. However, the uppermost wiring WL1 among the plurality of wirings WL1 is covered with the first layer ILD2a. The wiring WL2 is covered with the interlayer insulating film ILD3. A barrier film BF1 may be arranged between the lower surface of the wiring WL and the interlayer insulating film ILD, and a barrier film BF2 may be arranged on the upper surface of the wiring WL. The materials of the barrier film BF1 and the barrier film BF2 are, for example, titanium nitride.

Although not illustrated, a contact plug CP is buried in a contact hole formed in the lowermost interlayer insulating film ILD1 among the plurality of interlayer insulating films ILD1. The contact plug CP electrically connects the lowermost wiring WL1 among the plurality of wirings WL1 and the transistor TR to each other.

One wiring WL and another wiring WL arranged over the one wiring WL are electrically connected to each other by a via plug VP1 buried in a via hole formed in the interlayer insulating film ILD. The materials configuring the contact plug CP and the via plug VP1 are, for example, tungsten.

The resistor RES1, the resistor RES2, the resistor RES3, and the resistor RES4 are arranged on the first layer ILD2a. The resistor RES1, the resistor RES2, the resistor RES3, and the resistor RES4 are covered by the second layer ILD2b. The resistor RES1, the resistor RES2, and the resistor RES3 are electrically connected to the uppermost wiring WL1 among the plurality of wirings WL1 by a via plug VP2. The resistor RES4 may not be electrically connected to the wiring WL, meaning, the resistor RES4 may be a dummy resistor. The via plug VP2 is buried in a via hole formed in the first layer ILD2a. The material configuring the via plug VP2 is, for example, tungsten.

The second layer ILD2b is arranged on the first layer ILD2a so as to cover the resistor RES1, the resistor RES2, the resistor RES3, and the resistor RES4. The interlayer insulating film ILD3 is arranged on the second layer ILD2b. The wirings WL (wirings WL2, WL3) arranged above the resistor RES1 to the resistor RES4 are arranged in plan view so as not to overlap the resistor RES2. Moreover, the wiring WL2 and the wiring WL3 arranged above the resistor RES1 to the resistor RES4 may be arranged to overlap or not overlap the resistor RES1 (the resistor RES3, the resistor RES4).

As shown in FIGS. 1 and 2, the resistor RES1, the resistor RES3, and the resistor RES4 are arranged inside the resistor array region R1 in plan view. The resistor RES2 is arranged inside the adjustment region R2 in plan view, meaning, the resistor RES2 is arranged outside the resistor array region R1 in plan view.

The resistor array region R1 includes a region R1a, a region R1b, and a region R1c. In plan view, the region R1a, the region R1b, and the region R1c are arranged in a row. The plurality of regions included in the resistor array region R1 are arranged along a first direction DR1.

Inside one region R1a, the plurality of resistors RES1 are arranged along the first direction DR1. The longitudinal direction of the resistor RES1 in plan view is along a second direction DR2, which is perpendicular to the first direction DR1 in plan view. The number of resistors RES1 arranged in one region R1a may differ from the number of resistors RES1 arranged in another region R1a. Inside one region R1b, the plurality of resistors RES3 are arranged along the first direction DR1. The longitudinal direction of the resistor RES3 in plan view is along the second direction DR2. The number of resistors RES3 arranged in one region R1b may differ from the number of resistors RES3 arranged in another region R1b. Inside one region R1c, the plurality of resistors RES4 are arranged along the first direction DR1.

The region R1a is arranged between two regions R1b along the first direction DR1. That is, any of the plurality of regions R1a is arranged closer to a center C of the resistor array region R1 in the first direction DR1 than either region R1b or region R1c. The region R1b is arranged between the region R1a and the region R1c along the first direction DR1. That is, any of the plurality of regions R1b is arranged closer to the center C in the first direction DR1 than the region R1c. From another perspective, the region R1c is arranged at both ends of the resistor array region R1 along the first direction DR1.

The material of the resistor RES1, the material of the resistor RES2, the material of the resistor RES3, and the material of the resistor RES4 are a first material. The first material is, for example, silicon chromium (SiCr). However, the first material is not limited to this.

One of the temperature coefficient of the resistor RES1 and the temperature coefficient of the resistor RES2 is a positive value, and the other of the temperature coefficient of the resistor RES1 and the temperature coefficient of the resistor RES2 is a negative value. For example, the temperature coefficient of the resistor RES1 is a negative value, and the temperature coefficient of the resistor RES2 is a positive value. A temperature coefficient of a resistor is the rate of change of the electrical resistance value of the resistor per unit temperature. If the electrical resistance value of the resistor increases with the rise in temperature, the temperature coefficient of the resistor is a positive value. On the other hand, if the electrical resistance value of the resistor decreases with the rise in temperature, the temperature coefficient of the resistor is a negative value.

The plurality of resistors RES1, which are arranged in one region R1a, are electrically connected in series to each other. The plurality of resistors RES1, which are arranged in one region R1a and are electrically connected in series to each other, configure a resistor element RE1 by being electrically connected in series to the resistor RES2. The plurality of resistors RES3, which are arranged in one region R1b, configure a resistor element RE2 by being electrically connected in series to each other. That is, the resistor element RE2 is arranged inside the resistor array region R1.

It is preferable that the length of the resistor RES2 in the longitudinal direction is greater than the length of the resistor RES1 in the longitudinal direction. It is preferable that the width of the resistor RES2 in the direction perpendicular to the longitudinal direction is greater than the width of the resistor RES1 in the direction perpendicular to the longitudinal direction. The width of the resistor RES4 is, for example, greater than the width of the resistor RES1.

The semiconductor device DEV1 has a plurality of circuits configured by the transistors TR. The circuit included in the semiconductor device DEV1 includes a first circuit and a second circuit. The precision of the resistor element required for the first circuit is higher than the precision of the resistor element required for the second circuit.

The first circuit is, for example, a reference voltage generation circuit, a first digital-to-analog conversion circuit, and a second digital conversion circuit. The second circuit is, for example, a third digital-to-analog conversion circuit. The precision of the resistor element required for the third digital-to-analog conversion circuit is lower than the precision of the resistor element required for the first digital-to-analog conversion circuit and the second digital-to-analog conversion circuit. The resistor element RE1 is, for example, connected to the first circuit. The resistor element RE2 is, for example, connected to the second circuit. The resistor element RE2 may be used as a feedback resistor.

### Manufacturing Method of Semiconductor Device DEV1

Hereinafter, the manufacturing method of the semiconductor device DEV1 is described.

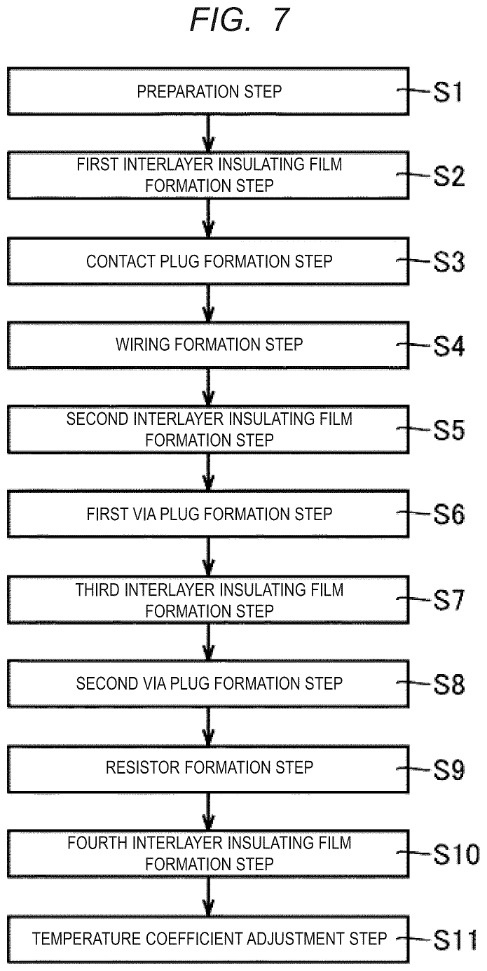

As shown in FIG. 7, the manufacturing method of the semiconductor device DEV1 includes a preparation step S1, a first interlayer insulating film formation step S2, a contact plug formation step S3, a wiring formation step S4, a second interlayer insulating film formation step S5, a first via plug formation step S6, a third interlayer insulating film formation step S7, a second via plug formation step S8, a resistor formation step S9, a fourth interlayer insulating film formation step S10, and a temperature coefficient adjustment step S11.

In the preparation step S1, the semiconductor substrate SUB is prepared. In the preparation step S1, the semiconductor substrate SUB, which already has the transistor TR formed thereon, is prepared. In the first interlayer insulating film formation step S2, the lowermost layer of the plurality of interlayer insulating films ILD1, which covers the transistor TR, is formed. In the first interlayer insulating film formation step S2, firstly, a material for the lowermost layer of the plurality of interlayer insulating films ILD1 is deposited on the semiconductor substrate SUB by, for example, a Chemical Vapor Deposition (CVD) method. Secondly, the material of the lowermost layer of the plurality of interlayer insulating films ILD1 that has been deposited is planarized by, for example, a Chemical Mechanical Polishing (CMP) method.

In the contact plug formation step S3, the contact plug CP is buried in the lowermost layer of the plurality of interlayer insulating films ILD1. In the contact plug formation step S3, firstly, a contact hole is formed in the lowermost layer of the plurality of interlayer insulating films ILD1 by etching using a resist pattern formed on the lowermost layer of the plurality of interlayer insulating films ILD1 by a photolithography method as a mask. Secondly, a material for the contact plug CP is buried in the contact hole by, for example, a CVD method. Thirdly, the material of the contact plug CP formed outside the contact hole is removed by, for example, a CMP method.

In the wiring formation step S4, the wiring WL1 is formed on the interlayer insulating film ILD1. In the wiring formation step S4, firstly, materials for the barrier film BF1, the wiring WL1, and the barrier film BF2 are sequentially deposited on the interlayer insulating film ILD1 by, for example, a sputtering method. Secondly, the deposited materials are patterned by etching using a resist pattern formed on the deposited material of the barrier film BF2 by a photolithography method as a mask.

In the second interlayer insulating film formation step S5, the interlayer insulating film ILD1 is formed to cover the wiring WL1. In the second interlayer insulating film formation step S5, firstly, a material for the interlayer insulating film ILD1 is deposited on the interlayer insulating film ILD1 by, for example, a CVD method. Secondly, the deposited material of the interlayer insulating film ILD1 is planarized by, for example, a CMP method.

In the first via plug formation step S6, the via plug VP1 is buried in the interlayer insulating film ILD1. In the first via plug formation step S6, firstly, a via hole is formed in the interlayer insulating film ILD1 by etching using a resist pattern formed on the interlayer insulating film ILD1 by a photolithography method as a mask. Secondly, a material for the via plug VP1 is buried in the via hole by, for example, a CVD method. Thirdly, the material configuring the via plug VP1 formed outside the via hole is removed, for example, by the CMP method.

Subsequently, by repeating the wiring formation step S4, the second interlayer insulating film formation step S5, and the first via plug formation step S6, the wiring WL1, the interlayer insulating film ILD1, and the via plug VP1 may be further formed.

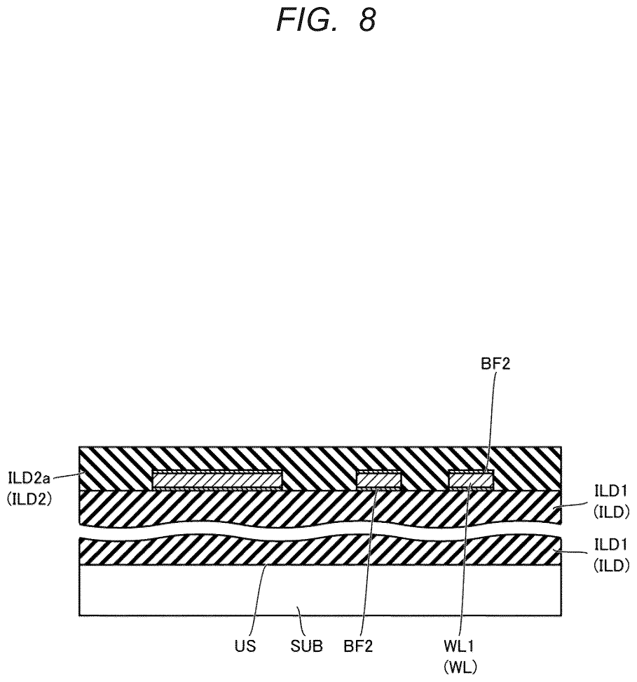

As shown in FIG. 8, in the third interlayer insulating film formation step S7, the first layer ILD2a is formed so as to cover the uppermost wiring WL1 among the plurality of wirings WL1. In the third interlayer insulating film formation step S7, firstly, the material configuring the first layer ILD2a is deposited, for example, by the CVD method, on the uppermost interlayer insulating film ILD1 among the plurality of interlayer insulating films ILD1. Secondly, the deposited material of the first layer ILD2a is planarized, for example, by the CMP method.

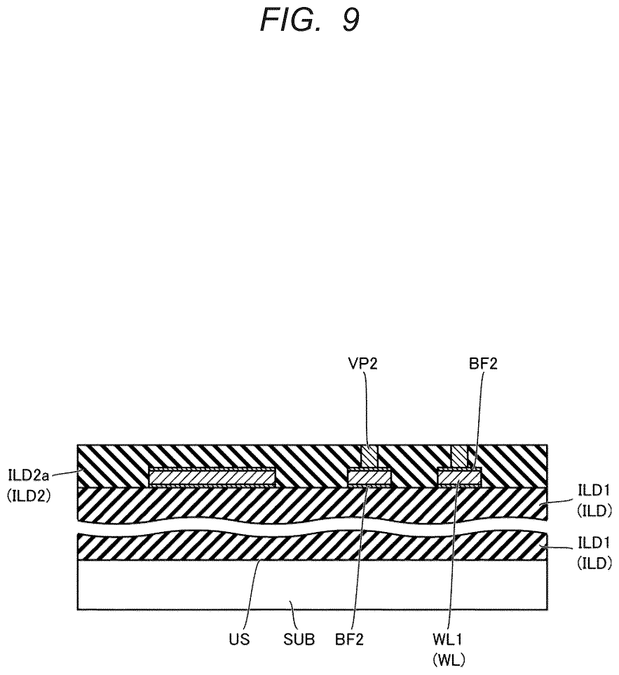

As shown in FIG. 9, in the second via plug formation step S8, the via plug VP2 is buried in the first layer ILD2a. In the second via plug formation step S8, firstly, a via hole is formed in the first layer ILD2a by etching using a resist pattern formed on the first layer ILD2a by photolithography as a mask. Secondly, the material configuring the via plug VP2 is buried in the via hole, for example, by the CVD method. Thirdly, the material configuring the via plug VP2 formed outside the via hole is removed, for example, by the CMP method.

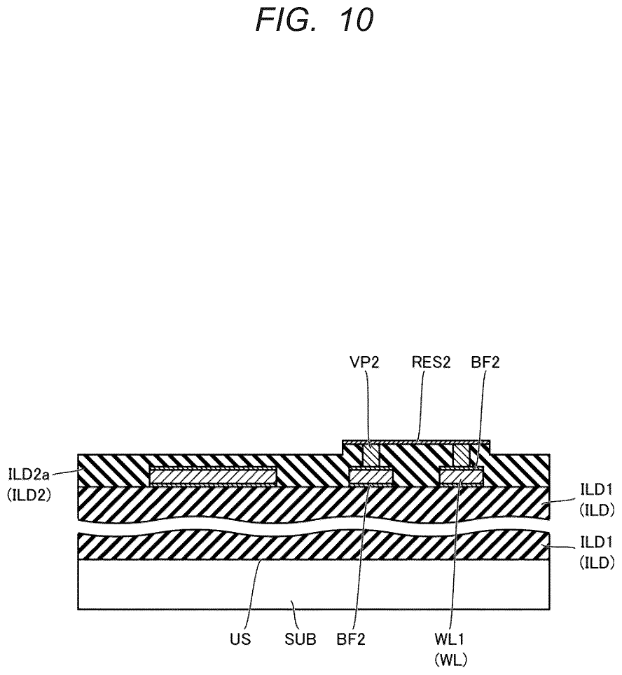

As shown in FIG. 10, in the resistor formation step S9, the resistor RES2 is formed on the first layer ILD2a. In the resistor formation step S9, firstly, the material configuring the resistor RES2 is deposited on the first layer ILD2a, for example, by the sputtering method. Secondly, the deposited material of the resistor RES2 is patterned by etching using a resist pattern formed on the deposited material of the resistor RES2 by photolithography as a mask. Although not shown, the resistor RES1, the resistor RES3, and the resistor RES4 are also formed similarly in the resistor formation step S9.

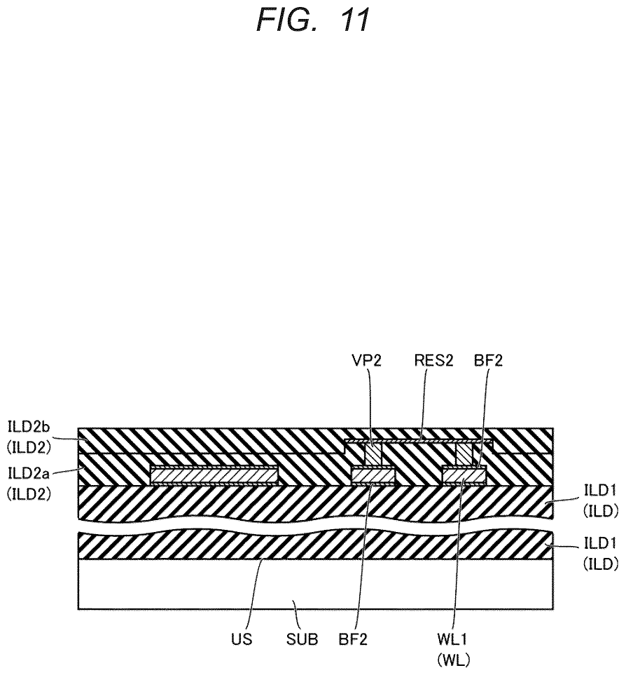

As shown in FIG. 11, in the fourth interlayer insulating film formation step S10, the second layer ILD2b is formed so as to cover the resistor RES1, the resistor RES2, the resistor RES3, and the resistor RES4. In the fourth interlayer insulating film formation step S10, firstly, the material configuring the second layer ILD2b is deposited on the first layer ILD2a, for example, by the CVD method. Secondly, the deposited material of the second layer ILD2b is planarized, for example, by the CMP method.

After the fourth interlayer insulating film formation step S10 is performed, the wiring formation step S4, the second interlayer insulating film formation step S5, and the first via plug formation step S6 are performed, whereby the wiring WL2, the wiring WL3, the interlayer insulating film ILD3, and the via plug VP1 are further formed. Thus, the structure of the semiconductor device DEV1 is formed.

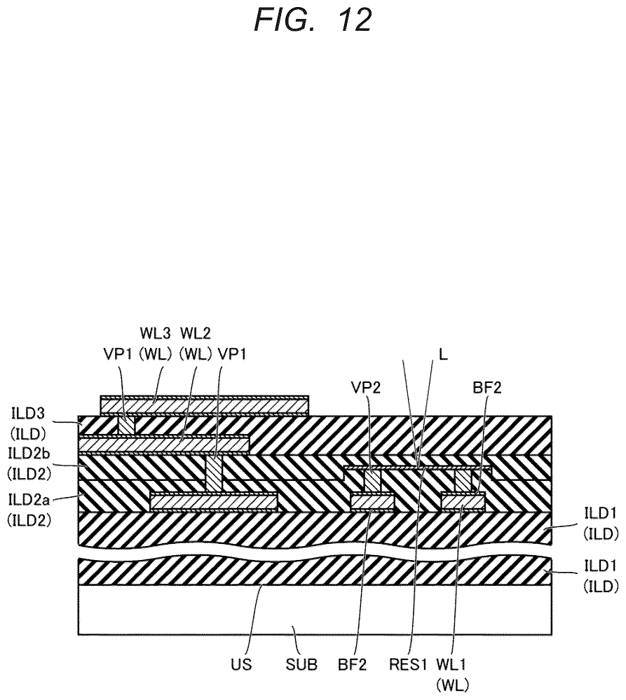

As shown in FIG. 12, in the temperature coefficient adjustment step S11, the temperature coefficient of the resistor RES2 is adjusted. More specifically, in the temperature coefficient adjustment step S11, local annealing is performed on the resistor RES2 by irradiating the resistor RES2 with laser light L through the interlayer insulating film ILD (second layer ILD2b, interlayer insulating film ILD3) arranged over the resistor RES2. As a result, the temperature coefficient of the resistor RES2 changes, and one of the resistor RES1 and the resistor RES2 has a positive temperature coefficient, while the other of the resistor RES1 and the resistor RES2 has a negative temperature coefficient. The conditions for annealing in the temperature coefficient adjustment step S11 are determined, for example, after measuring the temperature coefficient of the resistor RES1 and the temperature coefficient of the resistor RES2 before annealing.

### Effect of Semiconductor Device DEV1

The effect of the semiconductor device DEV1 is described below.

In the semiconductor device DEV1, one of the temperature coefficient of the resistor RES1 and the temperature coefficient of the resistor RES2 is a positive value, and the other of the temperature coefficient of the resistor RES1 and the temperature coefficient of the resistor RES2 is a negative value. Therefore, even if the temperature changes, the change in the electrical resistance value of the resistor RES1 and the change in the electrical resistance value of the resistor RES2 cancel each other out, thereby suppressing the change in the overall electrical resistance value of the resistor element RE1 due to temperature changes. Therefore, according to the semiconductor device DEV1, it is possible to reduce the temperature coefficient of the resistor element RE1, which has the resistor RES1 and the resistor RES2 formed of the same material as the resistor RES1.

In the semiconductor device DEVI, since the wiring WL (wiring WL2, wiring WL3) arranged above the resistor RES2 is arranged so as not to overlap the resistor RES2 in plan view, local annealing can be performed on the resistor RES2 by irradiating the resistor RES2 with laser light L. This makes it possible to form a resistor element that includes a resistor with a positive temperature coefficient and a resistor with a negative temperature coefficient.

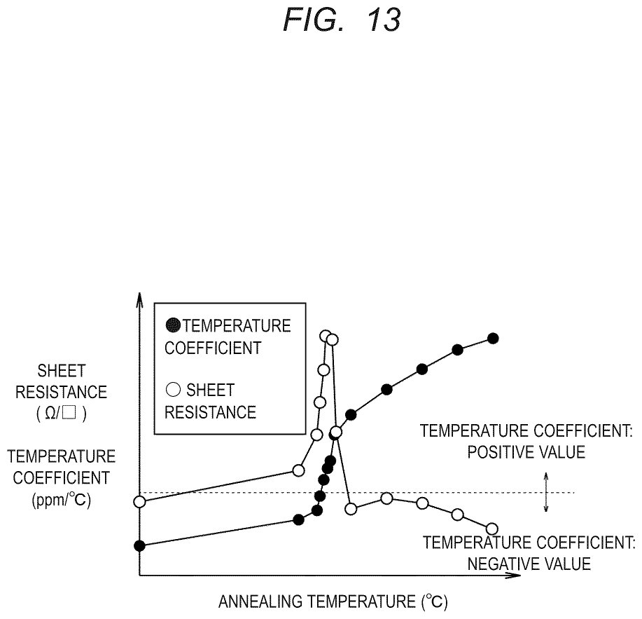

In FIG. 13, the vertical axis indicates the sheet resistance and temperature coefficient of the resistor RES2, and the horizontal axis indicates the annealing temperature. The graph in FIG. 13 is an example when the constituent material of the resistor RES2 is SiCr. As shown in FIG. 13, when annealing is performed on the resistor RES2, the temperature coefficient of the resistor RES2 changes from negative to positive. Therefore, as described above, by performing local annealing on the resistor RES2, it is possible to form a resistor element that includes a resistor with a positive temperature coefficient and a resistor with a negative temperature coefficient.

On the other hand, the electrical resistance (sheet resistance) of the resistor RES2 decreases due to annealing. The resistor element RE1 is configured by electrically connecting the resistor RES1 and the resistor RES2 in series to each other, and the electrical resistance value of the resistor element RE1 is represented by the sum of the electrical resistance values of the resistor RES1 and resistor RES2. Therefore, even if local annealing is performed on the resistor RES2 to adjust the temperature coefficient, the impact on the overall electrical resistance of the resistor element RE1 is minor. By making the length and width of the resistor RES2 greater than those of the resistor RES1, the impact of the decrease in the electrical resistance value of the resistor RES2 due to local annealing can be further reduced.

The temperature coefficient of the resistor element RE2 is not adjusted using the resistor RES2, thereby suppressing an increase in the number of steps associated with the adjustment of the temperature coefficient. Since the resistor element RE2 has relatively low requirements for the accuracy of the electrical resistance value, adjusting the temperature coefficient of the resistor element RE2 is not necessarily required.

In the semiconductor device DEV1, since the resistor RES2 is arranged in a different region (adjustment region R2) from the resistor array region R1, local annealing can be easily performed on the adjustment region R2 without affecting the resistors arranged in the resistor array region R1.

### Second Embodiment

A semiconductor device DEV2 according to the second embodiment is described. Here, mainly the differences from the semiconductor device DEV1 are explained, and repetitive explanations are not repeated.

### Configuration of Semiconductor Device DEV2

Hereinafter, the configuration of the semiconductor device DEV2 will be described.

The semiconductor device DEV2 includes the semiconductor substrate SUB, the interlayer insulating film ILD, the wiring WL, the contact plug CP, the via plug VP1, the via plug VP2, the resistor RES1, the resistor RES2, the resistor RES3, and the resistor RES4. Except for the region where the resistor RES2 is arranged, the configuration of the semiconductor device DEV2 is common with the configuration of the semiconductor device DEV1.

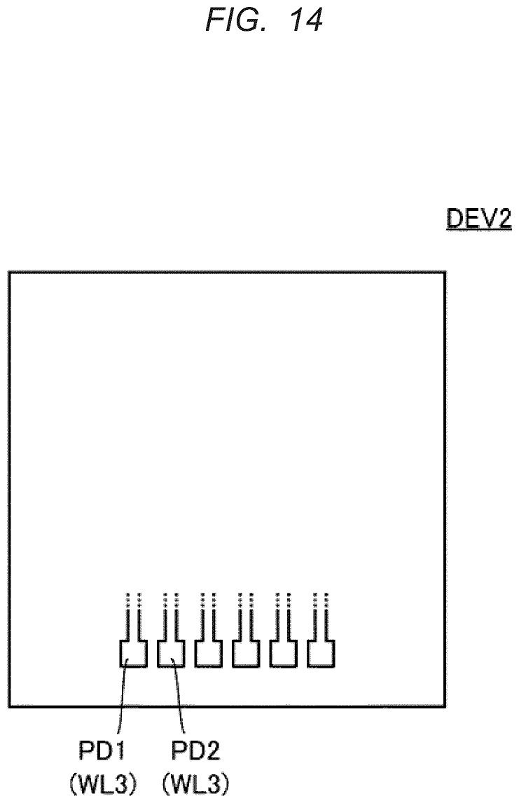

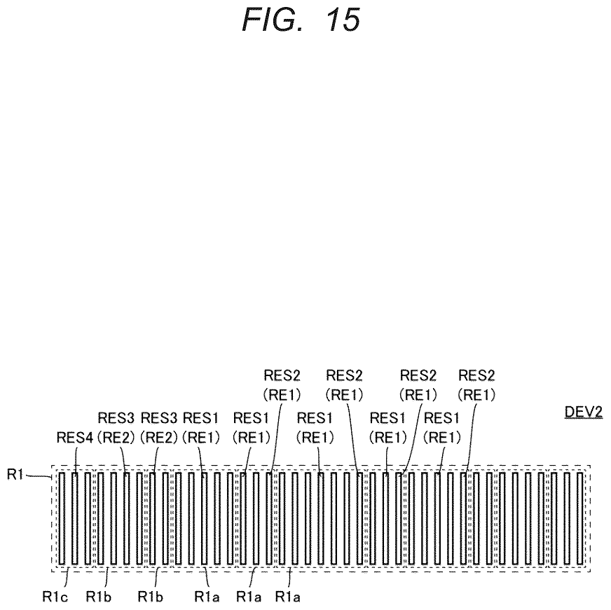

As shown in FIG. 14, in the semiconductor device DEV2, the wiring WL3 has a pad PD1 and a pad PD2. The pad PD1 and the pad PD2 are electrically connected to the resistor RES2 via the wiring WL, the via plug VP1, and the via plug VP2. As shown in FIG. 15, in the semiconductor device DEV2, the resistor RES2 is arranged inside the region R1a in plan view, alongside the resistor RES1. That is, in the semiconductor device DEV2, the resistor element RE1 is arranged inside the resistor array region R1. In these respects, the configuration of the semiconductor device DEV2 differs from the configuration of the semiconductor device DEV1.

In the semiconductor device DEV2, the wiring WL (wiring WL2, wiring WL3) arranged above the resistor RES1 to the resistor RES4 may be arranged to overlap the resistor RES2.

### Manufacturing Method of Semiconductor Device DEV2

The manufacturing method of the semiconductor device DEV2 is described below.

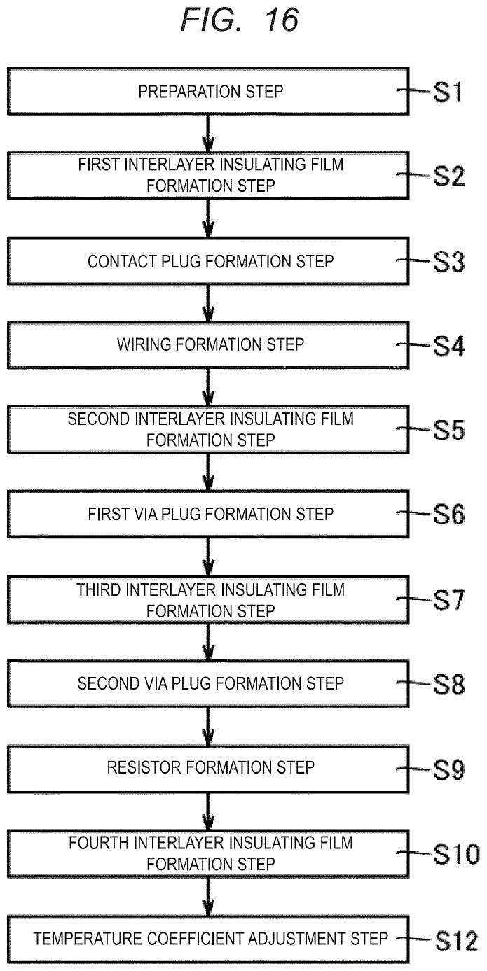

As shown in FIG. 16, the manufacturing method of the semiconductor device DEV2 includes the preparation step S1, the first interlayer insulating film formation step S2, the contact plug formation step S3, the wiring formation step S4, the second interlayer insulating film formation step S5, the first via plug formation step S6, the third interlayer insulating film formation step S7, the second via plug formation step S8, the resistor formation step S9, and the fourth interlayer insulating film formation step S10. In this respect, the manufacturing method of the semiconductor device DEV2 is common with the manufacturing method of the semiconductor device DEV1.

The manufacturing method of the semiconductor device DEV2 includes a temperature coefficient adjustment step S12 instead of the temperature coefficient adjustment step S11. In the temperature coefficient adjustment step S12, a voltage is applied between the pad PD1 and the pad PD2. As a result, current flows through the resistor RES2 causing the resistor RES2 to heat up, and a local annealing of the resistor RES2 is performed. The temperature coefficient adjustment step S12 may be performed during a wafer test step or an assembly step. In this respect, the manufacturing method of the semiconductor device DEV2 differs from the manufacturing method of the semiconductor device DEV1.

### Effect of Semiconductor Device DEV2

The effect of the semiconductor device DEV2 is described below.

In the semiconductor device DEV2, it is possible to perform local annealing to the resistor RES2 by locally flowing current through the resistor RES2. Therefore, in the semiconductor device DEV2, one of the temperature coefficient of the resistor RES1 and the temperature coefficient of the resistor RES2 can be set to a positive value and the other of the temperature coefficient of the resistor RES1 and the temperature coefficient of the resistor RES2 can be set to a negative value. Consequently, it is possible to reduce the temperature coefficient of the resistor element RE1 in the semiconductor device DEV2.

Moreover, when annealing the resistor RES2 by irradiating laser light L, similar to the semiconductor device DEVI, it is not possible to place the resistor RES2 near the resistor RES1 because the laser light L might also irradiate the resistor RES1. On the other hand, in the semiconductor device DEV2, since the annealing to the resistor RES2 is performed by locally flowing current, it is possible to place the resistor RES1 near the resistor RES2 and still perform local annealing to the resistor RES2. As a result, in the semiconductor device DEV2, it is unnecessary to allocate a region (for example, adjustment region R2) for placing the resistor RES2 other than the resistor array region R1, enabling the reduction of chip area.

### Third Embodiment

A semiconductor device DEV3 according to the third embodiment will be described. Here, mainly the differences from the semiconductor device DEV2 will be explained, and repetitive explanations will not be repeated.

### Configuration of Semiconductor Device DEV3

The configuration of the semiconductor device DEV3 will be described below.

The semiconductor device DEV3 includes the semiconductor substrate SUB, the interlayer insulating film ILD, the wiring WL, the contact plug CP, the via plug VP1, the via plug VP2, the resistor RES1, the resistor RES2, the resistor RES3, the pad PD1, and the pad PD2. Except for the region where the resistor RES2 is arranged, the configuration of the semiconductor device DEV3 is common to that of the semiconductor device DEV2.

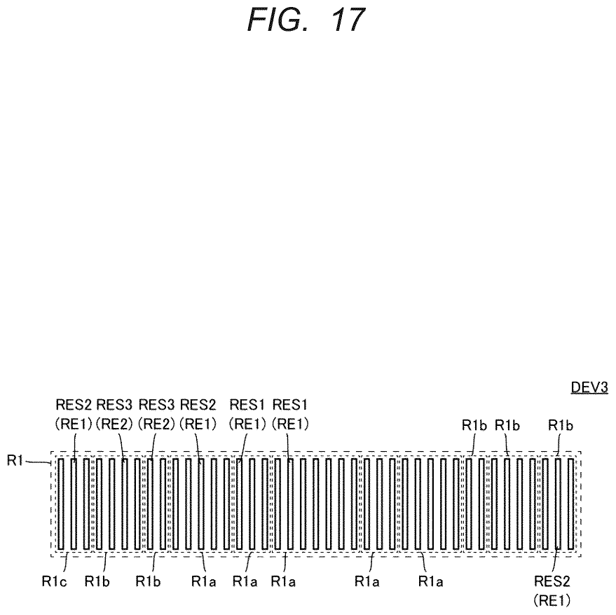

As shown in FIG. 17, the semiconductor device DEV3 does not have the resistor RES4. Also, in the semiconductor device DEV3, the resistor RES2 is arranged inside the region R1c. In these respects, the configuration of the semiconductor device DEV3 differs from that of the semiconductor device DEV2.

### Effect of Semiconductor Device DEV3

The effect of the semiconductor device DEV3 will be described below.

In the semiconductor device DEV3, the resistor RES2 is arranged inside the region R1c instead of the dummy resistor RES4. Therefore, in the semiconductor device DEV3, by arranging the resistor RES2 inside the region where the dummy resistor is arranged, it is possible to reduce the resistor array region R1, and it is possible to reduce the chip area.

Note that the width of the resistor (resistor RES2) arranged inside the region R1c is greater than the width of the resistor (resistor RES1) arranged inside the region R1a, so it is also possible to reduce the impact of the decrease in electrical resistance value due to annealing performed on the resistor RES2.

### Fourth Embodiment

A semiconductor device DEV4 according to the fourth embodiment will be described. Here, mainly differences from the semiconductor device DEV1 will be explained, and repetitive explanations will not be repeated.

### Configuration of Semiconductor Device DEV4

The configuration of the semiconductor device DEV4 will be described below.

The semiconductor device DEV4 includes the semiconductor substrate SUB, the interlayer insulating film ILD, the wiring WL, the contact plug CP, the via plug VP1, the via plug VP2, the resistor RES1, the resistor RES2, the resistor RES3, and the resistor RES4. Except for the layer where the resistor RES2 is arranged and the region where the resistor RES2 is arranged, the configuration of the semiconductor device DEV4 is common to that of the semiconductor device DEV1.

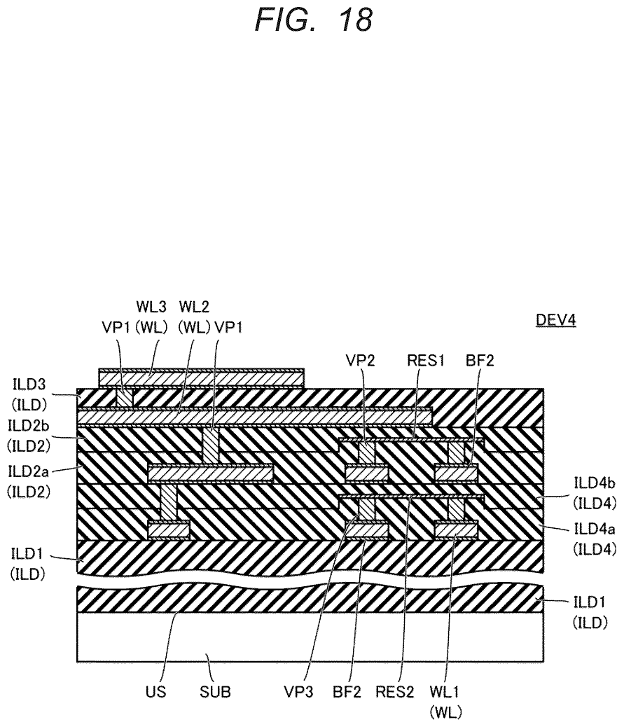

As shown in FIG. 18, in the semiconductor device DEV4, the resistor RES2 is arranged in a different layer from the resistor RES1. For example, in the semiconductor device DEV4, the resistor RES2 is arranged under the resistor RES1, not in the adjustment region R2.

More specifically, the interlayer insulating film ILD further includes an interlayer insulating film ILD4. The interlayer insulating film ILD4 is arranged on the uppermost interlayer insulating film ILD1 among the plurality of interlayer insulating films ILD1. The interlayer insulating film ILD4 includes a first layer ILD4a and a second layer ILD4b. The first layer ILD4a is interlayer arranged on the uppermost insulating ILD1 among the plurality of interlayer film insulating films ILD1 so as to cover the wiring WL1. The resistor RES2 is arranged on the first layer ILD4a and is electrically connected to the wiring WL2, which is covered by the first layer ILD4a, through a via plug VP3 buried in a via hole formed in the first layer ILD2a.

The second layer ILD4b is arranged on the first layer ILD4a so as to cover the resistor RES2. On the second layer ILD4b, the interlayer insulating film ILD2 (the first layer ILD2a) is arranged. That is, the resistor RES2 is arranged in a different layer from the resistor RES1. In these respects, the configuration of the semiconductor device DEV4 differs from that of the semiconductor device DEV1. Although not shown, the resistor RES3 and the resistor RES4 are arranged in the same layer as the resistor RES1.

### Manufacturing Method of Semiconductor Device DEV4

The manufacturing method of the semiconductor device DEV4 is described below.

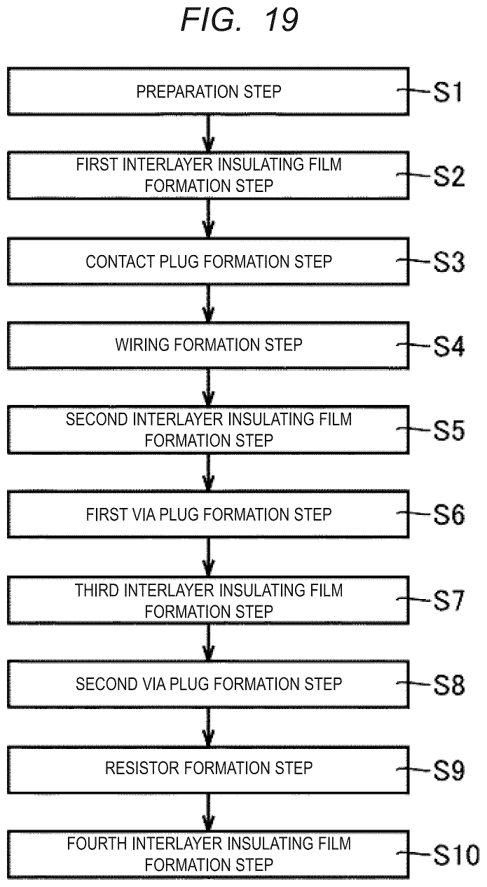

As shown in FIG. 19, the manufacturing method of the semiconductor device DEV4 includes the preparation step S1, the first interlayer insulating film formation step S2, the contact plug formation step S3, the wiring formation step S4, the second interlayer insulating film formation step S5, the first via plug formation step S6, the third interlayer insulating film formation step S7, the second via plug formation step S8, the resistor formation step S9, and the fourth interlayer insulating film formation step S10. In this respect, the manufacturing method of the semiconductor device DEV 4 is common to the manufacturing method of the semiconductor device DEV1.

The manufacturing method of the semiconductor device DEV4 does not include the temperature coefficient adjustment step S11. Furthermore, in the semiconductor device DEV4, by repeating the third interlayer insulating film formation step S7, the second via plug formation step S8, the resistor formation step S9, and the fourth interlayer insulating film formation step S10, the resistor RES1 is formed in the first layer, and the resistor RES2 is formed in a second layer, which is different from the first layer. In these respects, the manufacturing method of the semiconductor device DEV4 differs from the manufacturing method of the semiconductor device DEV1.

### Effect of The Semiconductor Device DEV4

The effects of the semiconductor device DEV4 are described below.

In the semiconductor device DEV4, since the resistor RES1 and the resistor RES2 are formed in different layers, the thermal history which the resistor RES1 experiences during the manufacturing step of the semiconductor device DEV4 is different from the thermal history which the resistor RES2 experiences. Additionally, by adding an annealing step between the steps of forming the resistor RES1 and the resistor RES2, it is possible to alter the thermal history which the resistor RES2 experiences. Therefore, even in the semiconductor device DEV4, one of the temperature coefficient of the resistor RES1 and the temperature coefficient of the resistor RES2 can be set to a positive value and the other of the temperature coefficient of the resistor RES1 and the temperature coefficient of the resistor RES2 can be set to a negative value, due to the difference in their thermal histories. Consequently, it is also possible to reduce the temperature coefficient of the resistor element RE1 in the semiconductor device DEV4.

### Fifth Embodiment

A semiconductor device DEV5 according to the fifth embodiment is described. Here, the differences from the semiconductor device DEV1 are mainly explained, and repetitive descriptions are not repeated.

### Configuration OF Semiconductor Device DEV5

The configuration of the semiconductor device DEV5 is described below.

The semiconductor device DEV1 includes the semiconductor substrate SUB, the interlayer insulating film ILD, the wiring WL, the contact plug CP, the via plug VP1, the via plug VP2, the resistor RES1, the resistor RES2, the resistor RES3, and the resistor RES4. In this respect, the configuration of the semiconductor device DEV5 is common to the configuration of the semiconductor device DEV1.

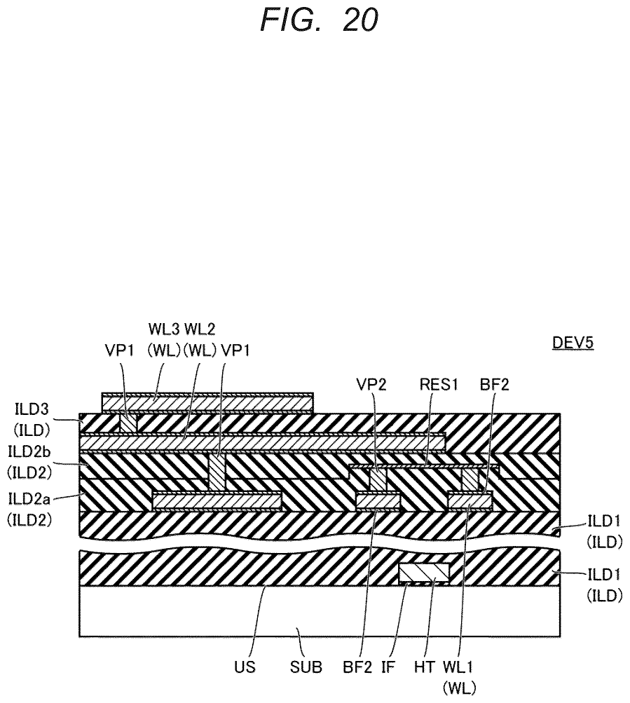

As shown in FIG. 20, the semiconductor device DEV5 further includes a heater HT. The heater HT is arranged to overlap the resistor RES2 in plan view. The heater HT is arranged on the upper surface US of the semiconductor substrate SUB via an insulating film IF. The material of the heater HT is the same type as the gate electrode of the transistor TR, for example, polycrystalline silicon. The material of the insulating film IF is the same type as the gate insulating film of the transistor TR, for example, silicon oxide.

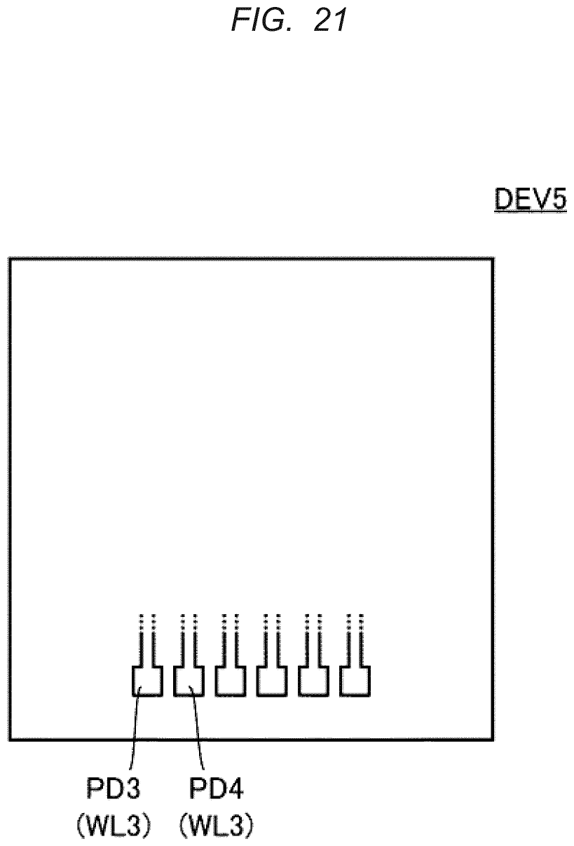

As shown in FIG. 21, in the semiconductor device DEV4, the wiring WL3 includes a pad PD3 and a pad PD4. The pad PD3 and the pad PD4 are electrically connected to the heater HT through the wiring WL, the via plug VP1, and the via plug VP2. In these respects, the configuration of the semiconductor device DEV5 differs from the configuration of the semiconductor device DEV1.

Note that the heater HT does not have to be arranged on the semiconductor substrate SUB, and the heater HT does not have to be formed of polycrystalline silicon (the same material as the gate electrode of the transistor TR). For example, the heater HT may be configured by electrically connecting the wiring WL, which overlaps the resistor RES2 in plan view, to the pad PD3 and the pad PD4.

### Manufacturing Method of Semiconductor Device DEV5

The manufacturing method of the semiconductor device DEV5 is described below.

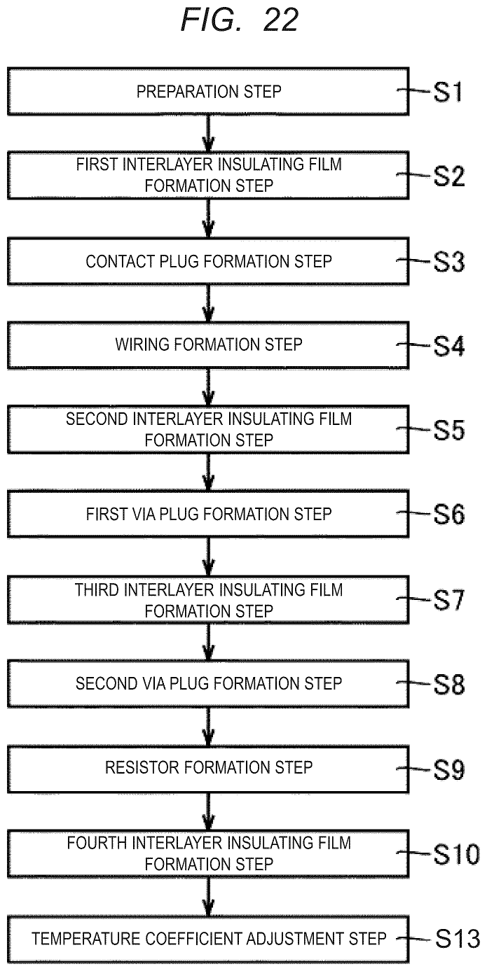

As shown in FIG. 22, the manufacturing method of the semiconductor device DEV5 includes the preparation step S1, the first interlayer insulating film formation step S2, the contact plug formation step S3, the wiring formation step S4, the second interlayer insulating film formation step S5, the first via plug formation step S6, the third interlayer insulating film formation step S7, the second via plug formation step S8, the resistor formation step S9, and the fourth interlayer insulating film formation step S10. In this regard, the manufacturing method of the semiconductor device DEV5 is common with the manufacturing method of the semiconductor device DEV1.

The manufacturing method of the semiconductor device DEV5 includes a temperature coefficient adjustment step S13 instead of the temperature coefficient adjustment step S11. In the temperature coefficient adjustment step S13, a voltage is applied between the pad PD3 and the pad PD4. As a result, current flows through heater HT causing it to generate heat, and a localized anneal is performed on the resistor RES2. Furthermore, the temperature coefficient adjustment step S13 may be performed during wafer test steps or assembly steps. In this regard, the manufacturing method of the semiconductor device DEV5 differs from the manufacturing method of the semiconductor device DEV1. In the manufacturing method of the semiconductor device DEV5, the insulating film IF is also formed when forming the gate insulating film of transistor TR, and the heater HT is also formed when forming the gate electrode of transistor TR.

### Effect of Semiconductor Device DEV5

The effect of the semiconductor device DEV5 is described below.

In the semiconductor device DEV5, it is possible to perform a localized anneal on the resistor RES2 by flowing current through the heater HT. Therefore, in the semiconductor device DEV5, one of the temperature coefficient of the resistor RES1 and the temperature coefficient of the resistor RES2 can be set to a positive value the other of the temperature coefficient of the resistor RES1 and the temperature coefficient of the resistor RES2 can be set to a negative value. Thus, it is possible to reduce the temperature coefficient of the resistor element RE1 in the semiconductor device DEV5. Since the heater HT is formed in the same process as the gate electrode of transistor TR, there is no need to add a new process for forming the heater HT.

Although the invention by the present inventor has been specifically described based on the embodiments, it is needless to say that the present invention is not limited to the above embodiments and can be modified in various ways without departing from the gist thereof.

What is claimed is:

1. A semiconductor device comprising:
a first resistor element,
wherein the first resistor element comprises:
a first resistor; and
a second resistor electrically connected in series to the first resistor,
wherein each of the first resistor and the second resistor is made of a first material,
wherein one of a temperature coefficient of an electrical resistance value of the first resistor and a temperature coefficient of an electrical resistance value of the second resistor is a positive value, and
wherein the other of the temperature coefficient of the electrical resistance value of the f resistor and the temperature coefficient of the electrical resistance value of the second resistor is a negative value.

2. The semiconductor device according to claim 1, further comprising:
a wiring formed above the second resistor,
wherein the wiring is arranged so as not to overlap the second resistor in plan view.

3. The semiconductor device according to claim 1,
wherein the first resistor is arranged inside a resistor array region in plan view, and
wherein the second resistor is arranged outside the resistor array region in plan view.

4. The semiconductor device according to claim 1, further comprising:
a first pad electrically connected to the second resistor; and
a second pad electrically connected to the second resistor.

5. The semiconductor device according to claim 4,
wherein the first resistor element is arranged inside a resistor array region in plan view,
wherein the resistor array region comprises a plurality of regions arranged in rows in plan view, and
wherein the first resistor and the second resistor are arranged inside a first region of the plurality of regions.

6. The semiconductor device according to claim 5, further comprising:
a second resistor element different from the first resistor element,
wherein the second resistor element comprises a third resistor,
wherein the third resistor is made of the first material,
wherein the second resistor element is arranged inside the resistor array region in plan view,
wherein the third resistor is arranged inside a second region of the plurality of regions, which is different from the first region, and
wherein the first region is arranged closer to a center of the resistor array region than the second region in a direction in which the plurality of regions are arranged.

7. The semiconductor device according to claim 3,
wherein the first resistor element is arranged inside the resistor array region in plan view,
wherein the resistor array region comprises a plurality of regions arranged in rows in plan view,
wherein the first resistor is arranged inside a first region of the plurality of regions,
wherein the second resistor is arranged inside a third region of the plurality of regions, which is different from the first region and arranged at an end of the resistor array region in a direction in which the plurality of regions are arranged.

8. The semiconductor device according to claim 1,
wherein the first resistor is formed in a first layer, and
wherein the second resistor is formed in a second layer different from the first layer.

9. The semiconductor device according to claim 8,
wherein the second resistor is formed above the first resistor.

10. The semiconductor device according to claim 1, further comprising:
a heater,
wherein the heater overlaps the second resistor in plan view.

11. The semiconductor device according to claim 10, further comprising:
a semiconductor substrate,
wherein a constituent material of the heater is polycrystalline silicon,
wherein the heater is arranged on the semiconductor substrate, and
wherein the heater is arranged under the second resistor.

12. The semiconductor device according to claim 1,
wherein the first material is SiCr.

13. The semiconductor device according to claim 1,
wherein a length and a width of the second resistor are greater than a length and a width of the first resistor.

14. A method of manufacturing a semiconductor device, the method comprising:
forming a first resistor and a second resistor electrically connected in series to the first resistor, from a first material; and
adjusting a temperature coefficient of an electrical resistance value of the second resistor such that one of a temperature coefficient of an electrical resistance value of the first resistor and the temperature coefficient of the electrical resistance value of the second resistor shows a positive value, and the other of the temperature coefficient of the electrical resistance value of the first resistor and the temperature coefficient of the electrical resistance value of the second resistor shows a negative value.

15. The method according to claim 14,
wherein the temperature coefficient of the second resistor is adjusted by irradiating the second resistor with laser light.

16. The method according to claim 14,
wherein the temperature coefficient of the second resistor is adjusted by flowing an electric current through the second resistor.

17. The method according to claim 14,
wherein the first resistor is formed in a first layer, and
wherein the temperature coefficient of the second resistor is adjusted by forming the second resistor in a second layer different from the first layer.

18. The method according to claim 14, further comprising:
forming a heater,
wherein the heater is formed to overlap the second resistor in plan view, and
wherein the temperature coefficient of the second resistor is adjusted by heating the second resistor with the heater.
